(19) United States
(12) Patent Application Publication
(10) Pub. No.: US 2025/0138078 A1
(43) Pub. Date: May 1, 2025

(54) System and Method of Power MOSFET Diagnostic and Lifetime Estimation Using AI Algorithm

(71) Applicants: Centre for Advances in Reliability and Safety Limited, Pak Shek Kok (HK); The Hong Kong Polytechnic University, Kowloon (HK)

(72) Inventors: Ka Hong LOO, Kowloon (HK); Hiu Hung LEE, Pak Shek Kok (HK); Chang LU, Pak Shek Kok (HK)

(21) Appl. No.: 18/931,749

(22) Filed: Oct. 30, 2024

(30) Foreign Application Priority Data
Nov. 1, 2023 (HK) 32023081996.5

(51) Int. Cl. G01R 31/26; G01N 29/06

(52) U.S. Cl. CPC G01R 31/2642; G01N 29/0681; G01N 29/069

(57) ABSTRACT

Disclosed is a power metal-oxide-semiconductor field-effect transistor (MOSFET) diagnostic and lifetime estimation system and method, including the steps of: acquiring degradation data by conducting a degradation test; measuring potential failure precursors to provide early warning of failure; inspecting and diagnosing health condition of internal structure of the power MOSFET device using thermal transient measurement and scanning acoustic microscopy (SAM) images; repeating power cycling test and the measurements of potential failure precursors until the precursors reach a corresponding failure threshold; and estimating remaining lifetime of the power MOSFET device using an artificial intelligence (AI) algorithm.

### CROSS-REFERENCE TO RELATED APPLICATIONS

Not applicable.

### FIELD OF THE INVENTION

The present invention relates to a system and method of power MOSFET diagnostic and lifetime estimation, in particular a health diagnostic and lifetime estimation method and system using an AI algorithm for power MOSFET.

### BACKGROUND OF THE INVENTION

The Metal Oxide Silicon Field Effect Transistors, commonly known as MOSFETs are electronic devices used to switch or amplify voltages in circuits. A power MOSFET is a specific type designed to handle significant power levels. The degradation of Power MOSFETs occupies a dominant position among the key factors affecting the reliability of power electronic circuits. Normally, the failure sites of the degraded power MOSFETs are inside the package and invisible from the outside, which makes it difficult to study the failure modes and mechanisms. Although there are several fault prediction methods and systems for power MOSFETs on the existing market, these methods and systems may not be able to detect and predict the failure of the internal structure and/or inside the package of the device.

The failure of the internal structure that was not detected or predicted may increase unexpected machine downtime and maintenance costs due to a sudden breakdown. Other than that, different failure modes of power MOSFETs may be detected by different failure precursors such as Drain-source on-state resistance (Rds,on), Gate threshold voltage (Vth), Diode Forward Voltage (Vsd), Zero Gate voltage drain current (Idss), Drain-source breakdown voltage (V(br) dss), Drain-source on-state voltage (Von), Input Capacitance (Ciss), Output Capacitance (Coss) and Reverse Capacitance (Crss). However, the current fault prediction method and system may not be able to detect a variety of different failure modes at the same time. Therefore, there is a need to have an improved method and system that can understand and detect different failure modes during the degradation of power MOSFETs.

China Patent Publication No. 107315138B discloses a fault prediction and health processing method and a test system for a power MOSFET. The method and system comprise the steps of: selecting a test sample of a MOSFET device, analyzing test data and establishing a characteristic parameter based on three parameters of drain-source voltage, drain current and device shell temperature. The failure threshold value is determined by the basic prior degradation model E, then the model E is trained by utilizing test data of the actual detected device, the characteristic parameters of the model are corrected, the residual service life of the MOSFET device is predicted by calculation, the health evaluation result is output, and the device is subjected to health processing. However, the method and system are based on physic-based modelling in predicting faults and health of MOSFETs. This may require fundamental knowledge of the MOSFET die degradation mechanism and the assembly-related parameters required to develop an accurate model. It also requires extensive data on the device's operating conditions, stress history and material properties. These data may not always be available or be difficult to obtain in practice. It also anticipates challenges when predicting the failure of complex systems in real-world applications without well-defined physical models to describe the degradation.

Korean Patent Publication No. 102452596 B1 discloses an apparatus and method for diagnosing MOSFETs. The apparatus is a device for diagnosing a MOSFET provided on a charge or discharge path of a cell assembly and configured to control conduction of a charge or discharge current, and is electrically connected to a gate terminal and a source terminal of the MOSFET. A processor is configured to diagnose whether the MOSFET is faulty by comparing the potential difference measurement value with a previously stored normal potential difference value. However, the apparatus and method do not disclose the lifetime estimation of power devices, which could provide an early warning to the user.

United States Patent Publication No. 20230194593 discloses a switching device in an alternate fuel transfer manifold and methods for estimating the remaining useful life of the switching device. The method comprises: estimating a health signature of the switching device while it is in use, calculating a health state estimation matrix by modelling the degradation of a health signature, determining the health state using the health state estimation matrix, forecasting and causing a notification to an output device. However, the method may not provide wide coverage of potential failure parameters in different aspects and capture all possible failure modes that may not be apparent from measuring just one or two parameters.

### SUMMARY OF THE INVENTION

It is an objective of the present invention to provide a health diagnostic and lifetime estimation method and system for power MOSFETs that adopts an AI algorithm that could determine different failure modes during the degradation of power MOSFETs and therefore improve the performance and reliability of the end products.

It is also an objective of the present invention to provide a non-destructive inspection method and system for power MOSFETs to check the health condition of an internal structure of the degraded devices easily and conveniently on a regular basis.

It is also a further objective of the present invention to provide a health diagnostic and lifetime estimation method and system for power MOSFETs that can provide early warning of potential failures, allow proactive maintenance and replacement of faulty devices, and therefore reduce unexpected machine downtime and maintenance costs.

It is also an objective of the present invention to provide a health diagnostic and lifetime estimation method and system for power MOSFETs that can be applied to different kinds of power devices and therefore cover a wide range of applications that require power switching and control.

Accordingly, these objectives may be achieved by following the teachings of the present invention. The present invention relates to a power metal-oxide-semiconductor field-effect transistor (MOSFET) diagnostic and lifetime estimation system, comprising: a data acquisition module with a degradation test setup and potential failure precursor measurements; a diagnostic module with a thermal transient measurement and a scanning acoustic microscopy; wherein a remaining lifetime of a power MOSFET device is estimated using an artificial intelligence (AI) algorithm.

### BRIEF DESCRIPTION OF DRAWINGS

The features of the invention will be more readily understood and appreciated from the following detailed description when read in conjunction with the accompanying drawings of the preferred embodiment of the present invention, in which:

FIG. 1 illustrates a flowchart diagram of the power MOSFET diagnostic and lifetime estimation method in the present invention;

FIGS. 2A-2B illustrate thermal transient measurement curves revealing the progress of degradation at the die-attach layer inside the package of DUTI and the intact curves for DUT10 without degradation at the die-attach layer;

FIGS. 3A-3C illustrate the results of die attach delamination, bond wire degradation, and health samples, respectively;

FIGS. 4A-4B illustrate failure precursors with predictable features for body diode voltage versus aged power cycles and on-state resistance versus aged power cycles in lifetime estimation, respectively;

FIGS. 5A-5C illustrate examples of prediction results for the failure precursors of the failed sample; and

FIGS. 6A-6C illustrate the performance prediction results of training and validation losses for Idss, Rds, On and Vsd.

### DETAILED DESCRIPTION OF THE INVENTION

For the purposes of promoting and understanding of the principles of the invention, reference will now be made to the embodiments illustrated in the drawings and described in the following written specification. It is understood that the present invention includes any alterations and modifications to the illustrated embodiments and includes further applications of the principles of the invention as would normally occur to one skilled in the art to which the invention pertains.

The present invention teaches a power metal-oxide-semiconductor field-effect transistor (MOSFET) diagnostic and lifetime estimation system, comprising: a data acquisition module comprises a degradation test setup and potential failure precursor measurements; a diagnostic module comprises a thermal transient measurement and a scanning acoustic microscopy; wherein a remaining lifetime of a power MOSFET device is estimated using an artificial intelligence (AI) algorithm.

In a preferred embodiment of the present invention, the power metal-oxide-semiconductor field-effect transistor (MOSFET) diagnostic and lifetime estimation system comprising: a data acquisition module with a power cycling test and potential failure precursor measurements; a diagnostic module with a thermal transient measurement and a scanning acoustic microscopy; wherein a remaining lifetime of a power MOSFET device is estimated using an artificial intelligence (AI) algorithm.

In a preferred embodiment of the present invention, the degradation test setup in the data acquisition module is a power cycling test and such power cycling test is conducted as an accelerated lifetime test (ALT) for acquiring degradation data. A thermo-sensitive electrical parameter (TSEP) is measured for conducting the power cycling test and is configured to indirectly determine junction temperature.

In a preferred embodiment of the present invention, the potential failure precursor measurements in the data acquisition module is configured to provide early warning of failure by measuring potential failure precursors against a pre-determined failure threshold through conducting power cycling tests.

In a preferred embodiment of the present invention, the potential failure precursors comprise Drain-source on-state resistance (Rds,on), Gate threshold voltage (Vth), Diode Forward Voltage (Vsd), Zero Gate voltage drain current (Idss), Drain-source breakdown voltage (V (br) dss), Drain-source on-state voltage (Von), Input Capacitance (Ciss), Output Capacitance (Coss) and Reverse Capacitance (Crss).

In a preferred embodiment of the present invention, the diagnostic module is configured to inspect and diagnose health condition of the internal structure (die-attach layer and bond wires) of the power MOSFET device using thermal transient measurement and scanning acoustic microscopy (SAM) images.

In a preferred embodiment of the present invention, the AI algorithm comprises a long short-term memory (LSTM) machine learning model 110 wherein the LSTM machine learning model is further trained and evaluated.

The present invention also teaches a method of power metal-oxide-semiconductor field-effect transistor (MOSFET) diagnostic and lifetime estimation 100, comprising the steps of: acquiring degradation data by conducting a degradation test; measuring potential failure precursors to provide early warning of failure 106; inspecting and diagnosing health condition of internal structure of the power MOSFET device using thermal transient measurement and scanning acoustic microscopy (SAM) images 108; repeating power cycling test and the measurements of potential failure precursors until the precursors reach a corresponding failure threshold; and estimating remaining lifetime of the power MOSFET device using an artificial intelligence (AI) algorithm.

In a preferred embodiment of the present invention, the acquiring of degradation data further comprises the steps of: performing a power cycling test on a power MOSFET device in the degradation test and measuring a thermo-sensitive electrical parameter (TSEP) to determine a junction temperature for the power cycling test 102; and repeating cycles of the power cycling test 104 with high current and high-temperature stress, followed by a period of relaxation at lower temperature and current.

In a preferred embodiment of the present invention, the estimating of remaining lifetime comprises the steps of: conducting data preparation and preprocessing to extract predictable features for prognostics and lifetime estimation 109; removing noise and normalizing the degradation data; and feeding the normalized degradation data into the AI algorithm; wherein the AI algorithm comprises a long short-term memory (LSTM) machine learning model 110.

In a preferred embodiment of the present invention, the removing of noise further comprises the step of: using a moving average filter (MAF) to avoid noise in the degradation data.

In a preferred embodiment of the present invention, the method further comprises the steps of: training the LSTM machine learning model with training data 112; predicting next value of the precursors of power MOSFETs 114; and evaluating the performance of neural network algorithm.

In a preferred embodiment of the present invention, the training of the model comprises the step of: using adaptive moment optimization (Adam) to optimize and adapt the learning rate for each neural network in model training.

In a preferred embodiment of the present invention, the method further comprises the steps of: dropping out regularization during training of the model; and using a predetermined batch size and a predetermined epoch size corresponding to size of degradation data and training data.

In a preferred embodiment of the present invention, the batch size is 32 and the epoch size is 50 to prevent overfitting.

The numbers for the batch size and for the epoch size are defined based on prediction results. It can be generalized to a range. For instance, the batch size can be determined based on the size of the dataset. The dataset for the prediction based on the precursor data is not very large in size, thus, a batch size between 32 to 128 is acceptable. Keeping the batch size small is one known way of preventing overfitting.

Similarly, the epoch size is set to 50 for a balance where the model should be able to achieve satisfactory performance and also not be time-consuming, based on the general dataset size for this kind of prediction.

In a preferred embodiment of the present invention, the method further comprises the step of simultaneously updating output feedback to the LSTM machine learning model.

### Example

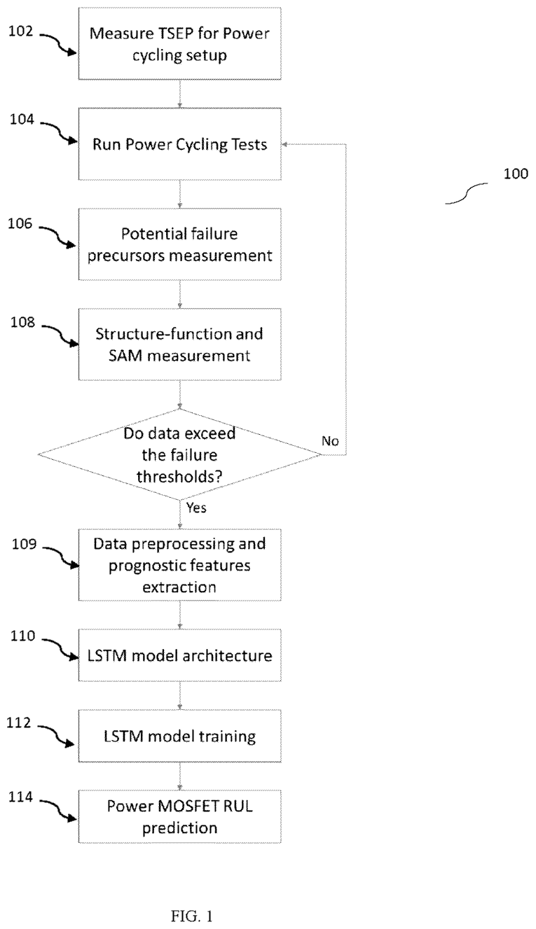

A flowchart diagram of the power MOSFET diagnostic and lifetime estimation in the present invention is illustrated in FIG. 1. The method comprises the steps of: acquiring degradation data; and measuring a thermos-sensitive electrical parameter (TSEP) to determine a junction temperature for a power cycling test setup under a constant junction temperature condition 102. The drain-source saturation voltage at a small, constant measurement current, which is approximately linearly dependent on the junction temperature, is used as the TSEP of the power MOSFETs. The method further comprises the step of running the power cycling tests 104. However, it is optional for the user to use other methods of acquiring degradation data, which subsequently do not need to determine or measure the TSEP.

The method further comprises the steps of measuring potential failure precursors to provide early warning of failure 106; inspecting and diagnosing health condition of the internal structure of the MOSFET device using thermal transient measurement and SAM images 108; repeating the power cycling test and measuring of potential failure precursors until the precursors reach a corresponding failure threshold. The repeating of the power cycling test includes high current and high temperature stress, followed by a period of relaxation at a lower temperature and current. The power cycling test provides a realistic simulation of the device's operation because it subjects the MOSFET to the same types of stresses that it would experience during normal use, such as temperature and current cycling. The said potential failure precursors comprise Rds, on, Vth, Vsd, Idss, V (br) dss, Von, Ciss, Coss, and Crss. The potential failure precursors are obtained and measured at the pristine stage and after certain power cycles, wherein these potential failure precursors are selected to represent the critical I-V and C-V characteristics of the power MOSFETs for a comprehensive diagnostic. The power cycle interval length is designed to ensure the data drifts can be captured precisely and not missed. Therefore, the present invention could identify different failure modes based on the corresponding changes in the failure precursors during the degradation of power MOSFETs and therefore improve the performance and reliability of the products.

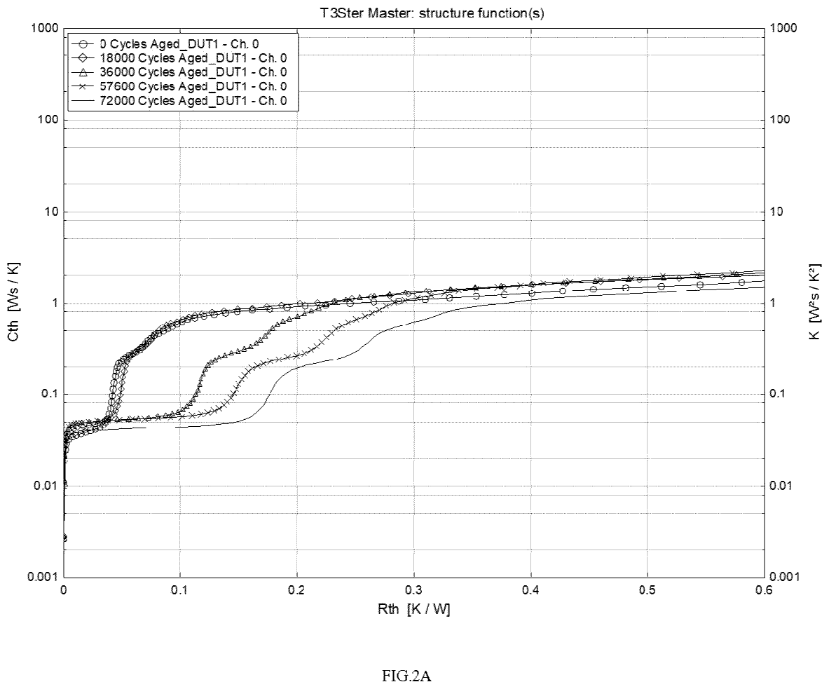

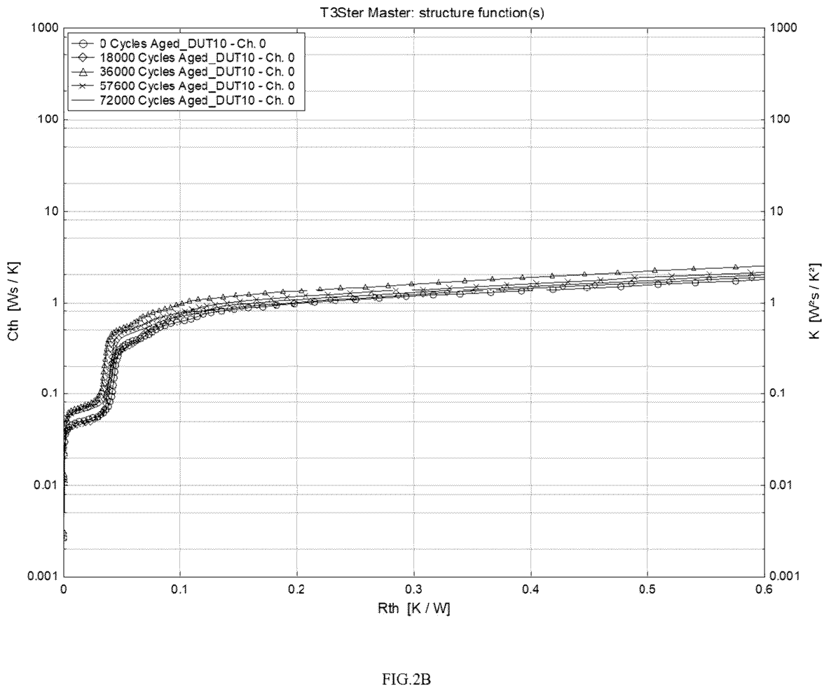

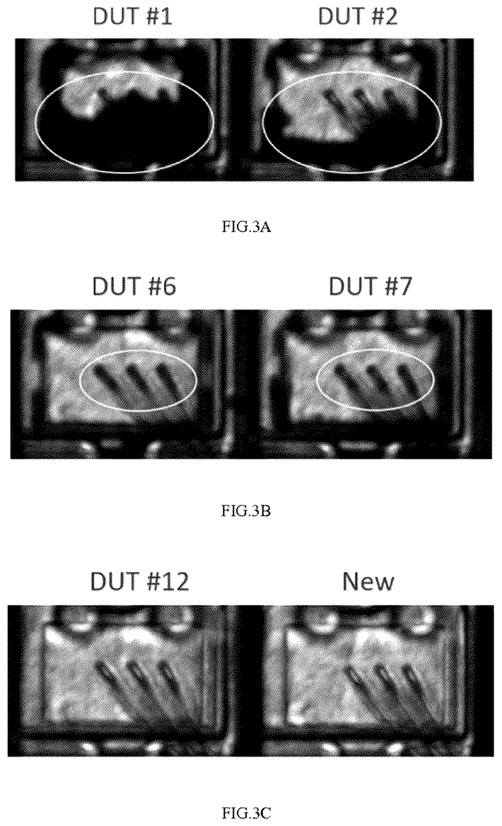

The thermal transient measurement and SAM image taking are performed regularly in the present invention to inspect and diagnose the health condition of the internal structure of the MOSFET device and correlate the changes in electrical parameters for the degraded devices. This is because usually, the failure sites of the degraded power MOSFETs are inside the package and invisible from the outside, which makes it difficult to study the failure modes and mechanisms. The thermal transient measurement shows the changes in the cumulative thermal capacitance and resistance along the heat flow path from the die to the substrate. FIG. 2 illustrates the thermal transient measurement curves, wherein FIG. 2A shows the changes of the curves which reveal the progress of the degradation at the die-attach layer inside the package of DUT1 and FIG. 2B shows the intact curves for DUT10 without degradation at the die-attach layer. The curve shifts to the right with the power cycling test continuing in FIG. 2A, wherein it indicates that the thermal resistance of the die-attach layer increases. The SAM images show any delamination or voids that occurred inside the package. The results of die attach delamination and bond wire degradation are observed in FIG. 3A and FIG. 3B, wherein FIG. 3C shows healthy samples. Therefore, the non-destructive inspection method of having the thermal transient measurement and SAM image could be beneficial for users to understand the physical changes that happened inside the package during sample degradation.

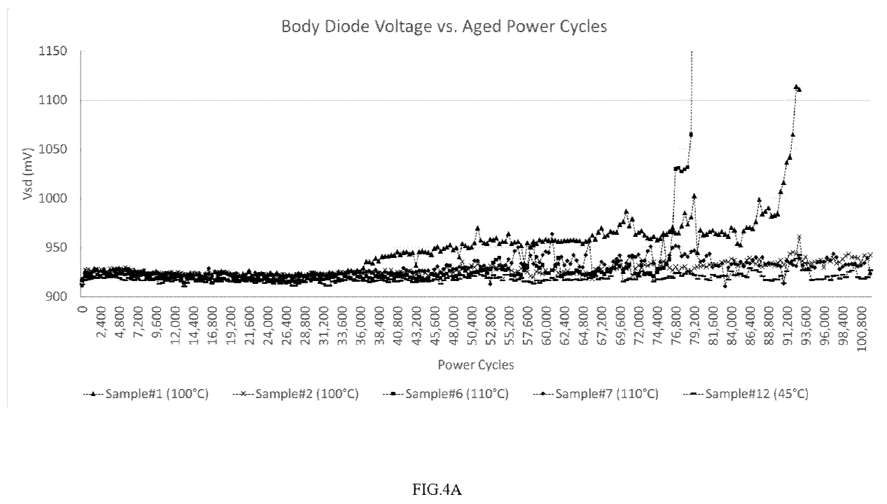

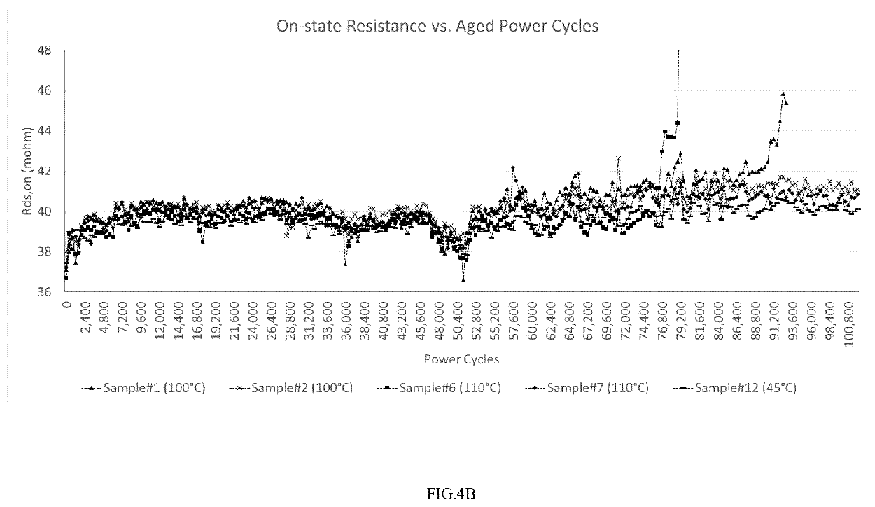

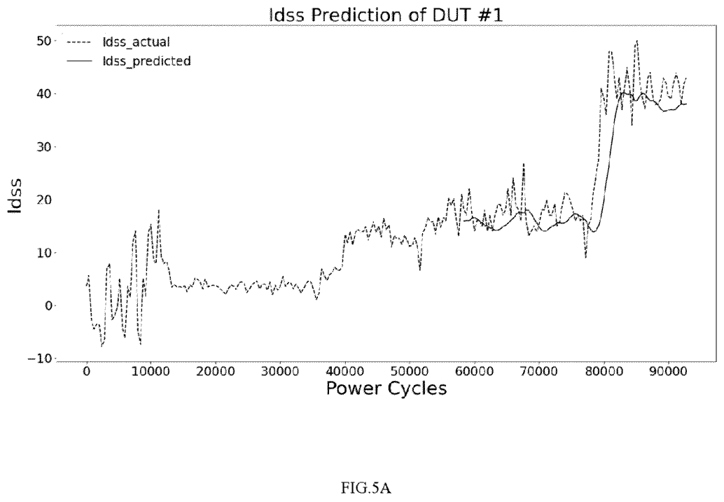

The power cycling tests will be repeated if the precursors do not exceed the failure thresholds by 20 percent of the initial values, whereas data preparation and preprocessing are conducted if the failure precursors exceed the failure thresholds. The precursors are considered failure precursors in the present invention as they have predictable features that can be used for lifetime estimation. FIG. 4A and FIG. 4B show the failure precursors with predictable features for body diode voltage versus aged power cycles and on-state resistance versus aged power cycles in lifetime estimation, respectively.

The method further comprises passing through the degradation data that exceeded failure thresholds with preliminary screening, removing noise, and normalizing. At this stage, the normalized data could be fed into the AI algorithm of the LSTM machine learning model. However, the simple moving average filter (MAF) with k=3 is further used in the present invention to avoid noise in the original data using the equation below:

$${x}_{k} = \frac{1}{k} {\sum }_{i = 1 - k + 1}^{n} {x}_{i} \qquad ( 1 )$$

The LSTM algorithm is used in the present invention to deal with time series data. 30 pieces of data are used for the prediction of the next data value. The LSTM model configuration is considered to have two hidden layers with 128 and 64 neurons and one output layer. The method further comprises training the LSTM model; and estimating the remaining lifetime of the power MOSFET device. Adam is used to optimize and adapt the learning rate for each neural network weight in model training. One of the common drawbacks of training neural network algorithms, in particular LSTM, is overfitting. Therefore, dropout regularization (0.2), an epoch size of 50, and a batch size of 32 are used in the present invention to prevent overfitting. The summary of the LSTM model architecture is listed in Table 1.

TABLE 1
Summary of the LSTM Model Architecture

| | Number of | | training loss | | |
|---|---|---|---|---|---|
| Model | Units | optimizer | function | Dropout | Activation |
| LSTM | (128, 64) | Adam | Mean Squared | 0.2 | relu |
| | | | Error | | |

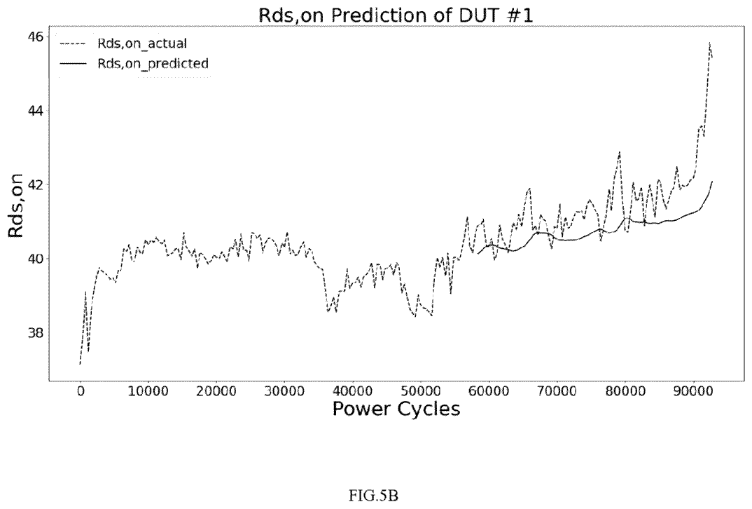

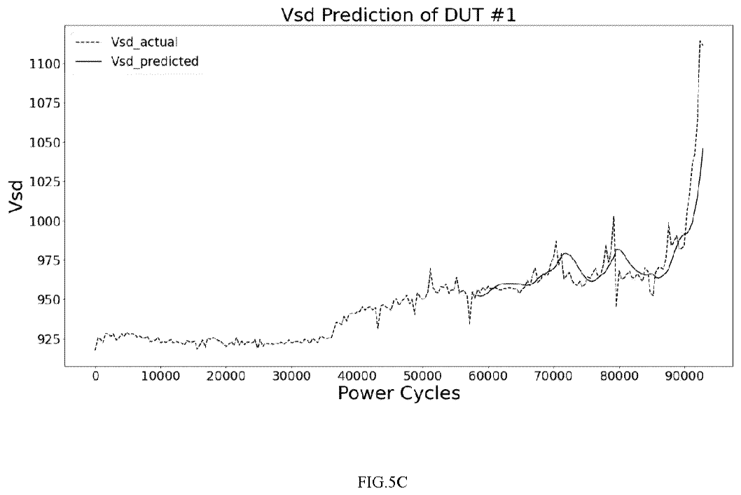

The examples of prediction results for the failure precursors of the failed sample are shown in FIGS. 5A-5C, with Idss prediction, Rds, on prediction, and Vsd prediction. The performance of the proposed algorithm is further evaluated in the present invention by calculating the loss in terms of MSE of the prediction results in the equation below:

$$MSE = \frac{1}{n} {\sum }_{i = 1}^{n} {e}_{i}^{2} = \frac{1}{n} {\sum }_{i = 1}^{n} {( {\hat{y}}_{i} - {\hat{y}}_{i} )}^{2} \qquad ( 2 )$$

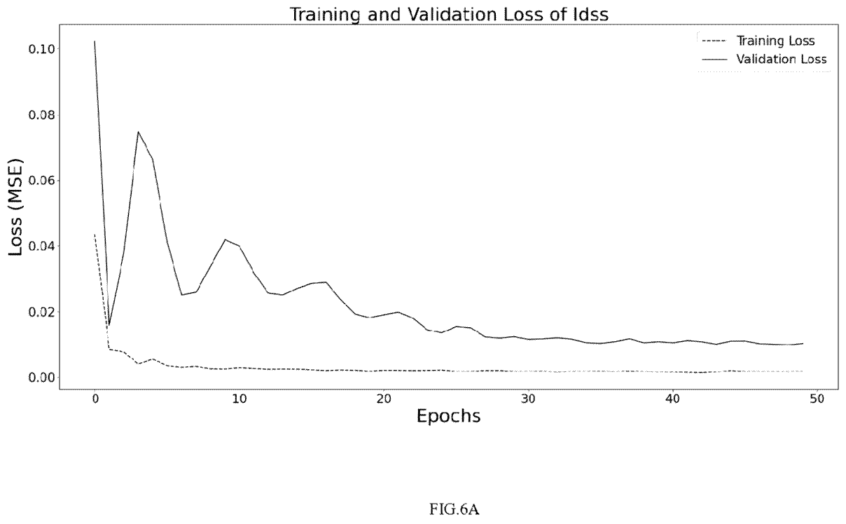

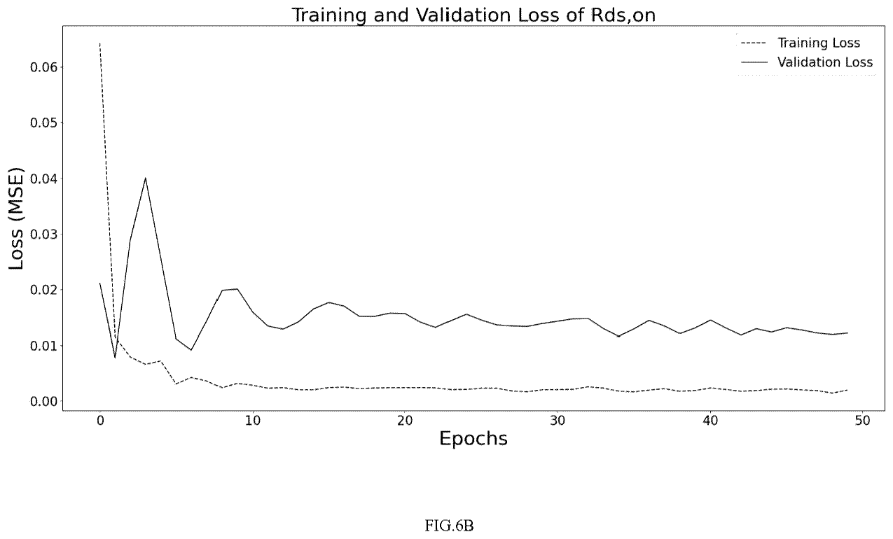

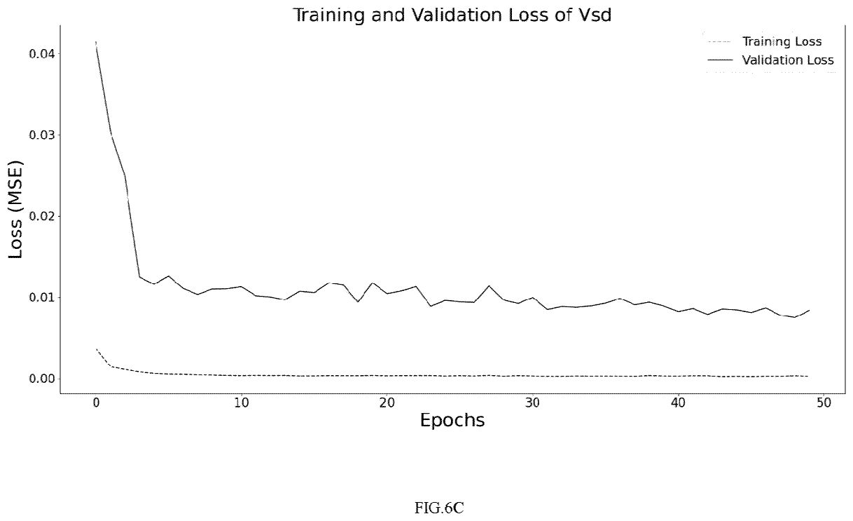

The performance prediction results of training and validation losses for Idss, Rds, On and Vsd are shown in FIGS. 6A-6C, respectively.

The power MOSFET diagnostic and lifetime estimation system and method in the present invention are useful for the maintenance of power systems by providing early warning of potential failures based on the collected failure precursor data, monitoring the internal health on a regular basis, and enabling the capture of abnormal behaviour before catastrophic failure happens. In addition, the lifetime of the power MOSFET can be estimated by the prediction results achieved from the failure precursor data with the aid of machine learning algorithms used in the present invention, allowing for proactive maintenance and replacement of faulty devices. The LSTM algorithm allows the degradation information to persist and is well-suited to capturing these nonlinear relationships between the inputs and the outputs. This makes data-driven models less complex and easier to develop compared to physics-based models. Therefore, this could reduce unexpected machine downtime and maintenance costs.

Furthermore, the power MOSFET diagnostic and lifetime estimation system and method in the present invention are not limited to a specific type of power MOSFET. The data-driven machine learning method in the present invention enables the possibility of applying it to different kinds of power devices, including but not limited to MOSFETs, IGBTs, SiC MOSFETs, etc. The active power cycling test in the present invention could reproduce the working conditions for different power devices due to their similarities in working principles, such as thermal stress under high power. The electrical characteristics of the power devices and the structure inside the package are also similar, so the methods are universally applicable. The machine learning algorithm is capable of handling time series data of different electrical parameters and devices, which therefore, the user could feed any data considered to have predictable features to the model for prediction. Accordingly, the system and method of the present invention could cover a wide range of applications that require power switching and control, including but not limited to automotive, aerospace, power generation, and telecommunications.

The present invention explained above is not limited to the aforementioned embodiment and drawings, and it will be obvious to those having an ordinary skill in the art of the present invention that various replacements, deformations, and changes may be made without departing from the scope of the invention.

1. A power metal-oxide-semiconductor field-effect transistor (MOSFET) diagnostic and lifetime estimation system, comprising:
a data acquisition module with a degradation test setup and potential failure precursor measurements;
a diagnostic module with a thermal transient measurement and a scanning acoustic microscopy;
wherein a remaining lifetime of a power MOSFET device is estimated using an artificial intelligence (AI) algorithm.

2. The power metal-oxide-semiconductor field-effect transistor (MOSFET) diagnostic and lifetime estimation system, according to claim 1, wherein the degradation test setup in the data acquisition module is a power cycling test and such power cycling test is conducted as an accelerated lifetime test (ALT) for acquiring degradation data.

3. The power metal-oxide-semiconductor field-effect transistor (MOSFET) diagnostic and lifetime estimation system, according to claim 2, wherein a thermo-sensitive electrical parameter (TSEP) is measured for conducting the power cycling test and is configured to indirectly determine junction temperature.

4. The power metal-oxide-semiconductor field-effect transistor (MOSFET) diagnostic and lifetime estimation system, according to claim 3, wherein the potential failure precursor measurements in the data acquisition module is configured to provide early warning of failure by measuring potential failure precursors against a pre-determined failure threshold through conducting power cycling tests.

5. The power metal-oxide-semiconductor field-effect transistor (MOSFET) diagnostic and lifetime estimation system, according to claim 4, wherein the potential failure precursors comprise Drain-source on-state resistance (Rds,on), Gate threshold voltage (Vth), Diode Forward Voltage (Vsd), Zero Gate voltage drain current (Idss), Drain-source breakdown voltage (V (br) dss), Drain-source on-state voltage (Von), Input Capacitance (Ciss), Output Capacitance (Coss) and Reverse Capacitance (Crss).

6. The power metal-oxide-semiconductor field-effect transistor (MOSFET) diagnostic and lifetime estimation system, according to claim 1, wherein the diagnostic module is configured to inspect and diagnose health condition of the internal structure of the power MOSFET device using thermal transient measurement and scanning acoustic microscopy (SAM) images.

7. The power metal-oxide-semiconductor field-effect transistor (MOSFET) diagnostic and lifetime estimation system, according to claim 1, wherein the AI algorithm comprises a long short-term memory (LSTM) machine learning model.

8. The power metal-oxide-semiconductor field-effect transistor (MOSFET) diagnostic and lifetime estimation system, according to claim 7, wherein the LSTM machine learning model is further trained and evaluated.

9. A method of power metal-oxide-semiconductor field-effect transistor (MOSFET) diagnostic and lifetime estimation, comprising the steps of:
acquiring degradation data by conducting a degradation test;
measuring potential failure precursors to provide early warning of failure;
inspecting and diagnosing health condition of internal structure of the power MOSFET device using thermal transient measurement and SAM images;
repeating power cycling test and the measurements of potential failure precursors until the precursors reach a corresponding failure threshold; and
estimating remaining lifetime of the power MOSFET device using an artificial intelligence (AI) algorithm.

10. The method of power metal-oxide-semiconductor field-effect transistor (MOSFET) diagnostic and lifetime estimation, according to claim 9, wherein the acquiring of degradation data further comprises the steps of:
performing a power cycling test on a power MOSFET device in the degradation test and measuring a thermos-sensitive electrical parameter (TSEP) to determine a junction temperature for the power cycling test; and
repeating cycles of the power cycling test (104) with high current and high-temperature stress, followed by a period of relaxation at lower temperature and current.

11. The method of power metal-oxide-semiconductor field-effect transistor (MOSFET) diagnostic and lifetime estimation, according to claim 9, wherein the estimating of remaining lifetime comprises the steps of:
conducting data preparation and preprocessing to extract predictable features for prognostics and lifetime estimation;
removing noise and normalizing the degradation data; and
feeding the normalized degradation data into the AI algorithm;
wherein the AI algorithm comprises a long short-term memory (LSTM) machine learning model.

12. The method of power metal-oxide-semiconductor field-effect transistor (MOSFET) diagnostic and lifetime estimation, according to claim 11, wherein the removing of noise further comprises the step of:
using a moving average filter (MAF) to avoid noise in the degradation data.

13. The method of power metal-oxide-semiconductor field-effect transistor (MOSFET) diagnostic and lifetime estimation, according to claim 11, wherein the method further comprises the steps of:
training the LSTM machine learning model with training data;
predicting next value of the precursors of power MOSFETs; and
evaluating the performance of neural network algorithm.

14. The method of power metal-oxide-semiconductor field-effect transistor (MOSFET) diagnostic and lifetime estimation, according to claim 13, wherein the training of the model comprises the step of:
using adaptive moment optimization (Adam) to optimize and adapt the learning rate for each neural network in model training.

15. The method of power metal-oxide-semiconductor field-effect transistor (MOSFET) diagnostic and lifetime estimation, according to claim 14, wherein the method further comprises the steps of:
dropping out regularization during training of the model; and
using a predetermined batch size and a predetermined epoch size corresponding to size of degradation data and training data.

16. The method of power metal-oxide-semiconductor field-effect transistor (MOSFET) diagnostic and lifetime estimation, according to claim 15, wherein the batch size is 32 and the epoch size is 50 to prevent overfitting.

17. The method of power metal-oxide-semiconductor field-effect transistor (MOSFET) diagnostic and lifetime estimation, according to claim 13, wherein the method further comprises the step of simultaneously updating output feedback to the LSTM machine learning model.
